(19) United States
(12) Patent Application Publication
(10) Pub. No.: US 2025/0340995 A1
(43) Pub. Date: Nov. 6, 2025

(54) A THERMALLY STABLE GRAPHENE-CONTAINING LAMINATE

(71) Applicant: Paragraf Limited, Somersham (GB)

(72) Inventors: Hugh Glass, Somersham (GB); Jaspreet Kainth, Somersham (GB); Rosie Baines, Somersham (GB); Ivor Guiney, Somersham (GB); Simon Buttress, Somersham (GB)

(73) Assignee: Paragraf Limited, Somersham (GB)

(21) Appl. No.: 18/872,016

(22) PCT Filed: Jun. 6, 2023
(86) PCT No.: PCT/EP2023/065142

§ 371 Date: Dec. 5, 2024

(30) Foreign Application Priority Data
Jun. 8, 2022 (GB) 2208400.8
Aug. 31, 2022 (GB) 2212645.2
Sep. 23, 2022 (GB) 2213925.7

(51) Int. Cl. C23C 28/04; G01R 33/07; H10N 52/85

(52) U.S. Cl. CPC C23C 28/04; G01R 33/07; H10N 52/85

(57) ABSTRACT

The present invention provides a graphene-containing laminate comprising. in order: a substrate: a graphene layer structure: a first metal oxide layer formed of a first metal oxide, wherein the first metal oxide is a transition metal oxide: and a second metal oxide layer formed of a second metal oxide: wherein the first metal oxide layer has a thickness of from 0.1 nm to 5 nm; and wherein the first metal oxide layer has a work function of 5 eV or more.

The present invention relates to a graphene-containing laminate and a method of manufacturing a graphene containing-laminate, together with electronic devices comprising said laminate, in particular Hall-sensors. The graphene-containing laminate has improved thermal stability over those known in the prior art and as such, there is provided a use of the device at elevated temperatures and prolonged times whereby the properties of the device remain sufficiently unchanged for reliable operation. More particularly, the graphene-containing laminate comprises a graphene layer structure having thereon a first metal oxide layer formed of a transition metal oxide followed by a second metal oxide layer.

Graphene is a leading two-dimensional material that has been incorporated in numerous products for its extraordinary properties. The electronic properties of graphene are especially remarkable and has allowed for the production of electronic devices (particularly microelectronics) that demonstrate properties that are orders of magnitude better than those of their non-graphene counterparts. Most notable is the use of graphene in electronic devices and their constituent components and includes transistors, LEDs, photovoltaic cells, Hall-effect sensors, diodes, electro-optic modulators (EOMs) and the like.

Accordingly, there are a wide range of electronic devices known in the prior art which have integrated graphene layer structures (single layer or multi-layer graphene) for delivering improvements in such devices over earlier devices and electronic products. These include structural improvements through the use of thinner and lighter materials (which can give rise to flexible electronics) as well as performance improvements such as increased electrical and thermal conductance leading to greater operating efficiencies.

It is known to provide graphene layer structures with a range of different charge carrier concentrations and that low values are useful for certain applications. Through changing growth conditions it is possible to optimise the charge carrier concentrations. The present inventors have found that the most effective method for manufacturing high-quality graphene, especially directly on substrates providing non-metallic surfaces suitable for subsequent use in electronic devices, is that disclosed in WO 2017/029470 (the contents of which is incorporated herein by reference in its entirety).

One way to reduce the charge carrier concentration further is with doping, and this is known from WO 2017/029470. This method involves the intentional introduction of dopants to counter-dope the graphene material and reduce the charge carrier concentration (e.g. n-type doping a p-type graphene layer). The method of WO 2017/029470 involves directly doping the graphene during production, such as by using CH₃Br as a precursor. However, the presence of dopant atoms can cause a reduction in carrier mobility due to scattering effects.

A further way to reduce the sheet carrier concentration is disclosed in WO 2021/008938 which relates to a method for the production of a polymer coated graphene layer structure. This publication discloses the formation of graphene on a substrate by CVD (preferably using a method as disclosed in WO 2017/029470), the graphene having a first charge carrier concentration, and coating the graphene layer structure with a polymer composition to form an impermeable coating, the coated graphene having a second charge carrier concentration that may be less than 10¹² cm⁻². Such a low charge carrier concentration is achieved through the use of a dopant in the coating to counteract the intrinsic doping of graphene formed directly on substrates by CVD.

GB 2601104 discloses forming an air-and/or moisture-barrier coating on graphene, the coating being formed from a composition comprising a precursor for an inorganic oxide, fluoride or sulfide barrier coating, the composition further comprising a doping agent which dopes the graphene. The charge carrier concentration of the coated graphene may be less than the uncoated graphene at less than 5×10¹² cm⁻², preferably less than 10¹² cm⁻².

Appl. Phys. Lett. 2010, 96, 213104 “Surface transfer hole doping of epitaxial graphene using MoO₃ thin film”, as well as US 2013/048952 A1 which shares a number of the authors as inventors, disclose hole doping of graphene through disposition of an MoO₃ layer to provide a hole density of about 1.0×10¹³ cm⁻².

Scientific Reports, 2014, 4, 5380 “Metal Oxide Induced Charge Transfer Doping and Band Alignment of Graphene Electrodes for Efficient Organic Light Emitting Diodes” similarly relates to MoO₃ layers on graphene and its incorporation in OLEDs. The purpose of MoO₃ in doping the graphene is to improve sheet resistance which is typically afforded by an increase is charge carriers such as holes. A ˜10% increase in sheet resistance is observed after storage in air.

C. 2019, 142, 468 “Gateless and reversible carrier density tunability in epitaxial graphene devices functionalized with chromium tricarbonyl” relates to devices with tuneable charge carrier density whereby carrier density is increased as a consequence of heat and returned to its low value within about 24 hours once the device was in air.

Despite these developments in the prior art, there remains a problem with graphene-based electronic devices in that the properties of the graphene are known to drift over time through use. Whilst the foregoing developments serve to provide the desirable electronic properties of, most particularly, charge carrier concentration, and protect the graphene from atmospheric contamination, the inventors have found that the deposited materials which were employed to function as barriers themselves result in doping of the graphene layer structure. As a result, the electronic properties of the graphene still succumb to drift and the inventors have sought to address this problem. Drift in charge carrier concentration is a significant problem in at least two key areas: (i) where a device is used at elevated temperatures (i.e. above ambient temperature such as in excess of 50° C.) whereby change in the charge carrier concentration is accelerated, and (ii) devices which rely on low charge carrier concentrations close to the Dirac point (e.g. less than 5×10¹² cm⁻², especially on the order of magnitude of 10¹¹ or 10¹⁰). When close to the Dirac point, a small change in charge carrier concentration correlates to a much greater relative change when compared to graphene having a much larger charge carrier concentration.

GB 2602119 relates to graphene Hall-sensors and methods of manufacture thereof and discloses patterning a dielectric by physical vapour deposition on graphene and which preferably further comprises forming an air-resistant coating. UK Patent Application No. 2203362.5 similarly relates to graphene Hall-sensors and methods of manufacture thereof and discloses forming a dielectric by ALD on graphene and a second dielectric thereon, wherein the production uses photolithography techniques. The contents of both documents are incorporated herein by reference in their entirety.

Whilst both references provide good quality graphene Hall-sensors, they can suffer from drift, particularly at elevated temperatures such that the graphene is not thermally stable and the device is not suitable for prolonged use at temperatures in excess of 50° C. without an inevitable drawback in performance or a need for more frequent calibration.

It is known to be problematic to deposit dielectric layers by ALD on the surface of pristine graphene (in particular graphene grown directly on a substrate which has not been transferred and therefore has significantly fewer defects). Adv. Mater. Interfaces 2017, 4, 1700232 “Atomic Layer Deposition for Graphene Device Integration” and Appl. Sci. 2020, 10(7), 2440 “Atomic Layer Deposition of High-k Insulators on Epitaxial Graphene: A Review” provide an in-depth overview regarding the growth of dielectric layers by ALD on graphene. Dielectric layers are key components of electronic devices, ALD is in various circumstances the preferred method of deposition since it can provide thin films of uniform thickness. This review looks at ALD on pristine graphene as well as on graphene having had “surface preparation” such as through the use of organic polymers or self-assembled monolayers, metal or metal oxide seed layers or surface functionalisation.

Addressing the problems with such “ex-situ” seeding, C. 2019, 5(3), 53 “Recent Advances in Seeded and Seed-Layer-Free Atomic Layer Deposition of High-K Dielectrics on Graphene for Electronics” reviews more recent developments of ALD of high-k dielectrics on graphene with “in-situ” seed-layer approaches.

ACS Nano 2010, 4, 5, 2667 “Epitaxial Graphene Materials Integration: Effects of Dielectric Overlayers on Structural and Electronic Properties” provides a study of the deposition of Al₂O₃, HfO₂, TiO₂ and Ta₂O₅ on epitaxial graphene through the use of seeds formed by deposition of metal and oxidation before deposition of an oxide by ALD.

The present invention seeks to provide improved graphene-containing laminates and associated electronic devices comprising the same which overcome, or substantially reduce, the various problems associated with the prior art or at least provide a commercially useful alternative.

According to a first aspect, the present invention provides a graphene-containing laminate comprising, in order:
a substrate;
a graphene layer structure;
a first metal oxide layer formed of a first metal oxide, wherein the first metal oxide is a transition metal oxide; and
a second metal oxide layer formed of a second metal oxide;
wherein the first metal oxide layer has a thickness of from 0.1 nm to 5 nm; and
wherein the first metal oxide layer has a work function of 5 eV or more.

According to a second aspect, the present invention also provides a method of forming a graphene-containing laminate, the method comprising:
providing a graphene layer structure on a substrate;
forming a first metal oxide layer on the graphene layer structure, wherein the first metal oxide layer is formed of a transition metal oxide and has a work function of 5 eV or more; and
forming a second metal oxide layer on the first metal oxide layer, wherein the second metal oxide layer is formed of a second metal oxide;
wherein the first metal oxide layer has a thickness of from 0.1 nm to 5 nm.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous. It is intended that the features disclosed in relation to the method may be combined with those disclosed in relation to the graphene-containing laminate and vice versa. Accordingly, the graphene-containing laminate is obtainable by the method and also the method is one suitable for manufacturing the graphene-containing laminate described herein.

The present invention relates to a graphene-containing laminate a method of forming a graphene-containing laminate. As described in greater detail herein, the graphene-containing laminate comprises a substrate having thereon, a graphene layer structure and first and second metal oxide layers. As such, there are no intervening layers between any given layer said to be “on” another layer.

Graphene is a very well-known two-dimensional material referring to an allotrope of carbon comprising a single layer of carbon atoms in a hexagonal lattice. Graphene, as used herein, refers to one or more layers of graphene. Accordingly, the present invention relates to the formation of a monolayer of graphene as well as multilayer graphene. Graphene, as used herein, refers to a graphene layer structure, preferably having from 1 to 10 monolayers of graphene. In many subsequent applications of a graphene-containing laminate, one monolayer of graphene is particularly preferred (especially for Hall-sensors). Accordingly, a graphene layer structure is preferably a graphene monolayer. Nevertheless, multilayer graphene may be preferable for certain applications in which case 2 or 3 layers of graphene may be preferred.

The graphene layer structure is provided on a substrate, preferably a non-metallic surface of a substrate. Preferably, the surface is an electrically insulative surface (for example, a substrate may be a silicon substrate having a silicon dioxide surface). The substrate may also be a CMOS wafer which may be silicon based and have associated circuitry embedded within the substrate. A substrate may also comprise one or more layers (for example, regions or channels of embedded waveguide materials such as silicon nitride suitable for EOMs). In another example, a substrate may comprise a non-metallic layer which provides a non-metallic growth surface, and a conductive layer (for example, silicon on insulator (SOI) substrates such as a silicon substrate having a silicon oxide layer). The conductive layer can serve as a contact for electronic devices.

Preferably, the non-metallic surface upon which the graphene layer structure is provided is silicon (Si), silicon carbide (SiC), silicon nitride (Si₃N₄), silicon dioxide (SiO₂), sapphire (Al₂O₃), aluminium gallium oxide (AGO), hafnium dioxide (HfO₂), zirconium dioxide (ZrO₂), yttria-stabilised hafnia (YSH), yttria-stabilised zirconia (YSZ), magnesium aluminate (MgAl₂O₄), yttrium orthoaluminate (YAlO₃), strontium titanate (SrTiO₃), cerium oxide (Ce₂O₃), scandium oxide (Sc₂O₃), erbium oxide (Er₂O₃), magnesium difluoride (MgF₂), calcium difluoride (CaF₂), strontium difluoride (SrF₂), barium difluoride (BaF₂), scandium trifluoride (ScF₃), germanium (Ge), hexagonal boron nitride (h-BN), cubic boron nitride (c-BN) and/or a III/V semiconductor such as aluminium nitride (AIN) and gallium nitride (GaN). Preferably, the substrate comprises silicon, silicon nitride, silicon dioxide, sapphire, aluminium nitride, YSZ, germanium and/or calcium difluoride. Preferably, the non-metallic surface is sapphire, yttria-stabilised zirconia or calcium difluoride, preferably wherein the sapphire is c-plane or r-plane sapphire (that is the surface provides the crystallographic c-plane or r-plane orientation). R-plane sapphire is preferred. In some embodiments, the substrate may consist of one such material.

The thickness of the substrate is not limited and may be any conventional thickness as is typical for electronic device substrates. Typically, the thickness of such substrates are 300 microns to 2 mm thick. In some preferred embodiments, a thin graphene-containing laminate, ultimately a thin electronic device, can be obtained by reducing the thickness of the substrate by thinning (for example, as described in GB Patent Application No. 2102218.1). Preferably such thinning is carried out on a silicon substrate having a thin insulative layer upon which the graphene layer structure is provided. Thinning may be carried out by etching with an etchant and/or grinding (preferably where etching follows a preliminary grinding). The substrate thickness after thinning may be 200 microns or less, preferably 100 microns or less. Such a step may also be referred to as “wafer backgrinding” and advantageously provides a thin temperature stable electronic device. Without wishing to be bound by theory, it is believed that thinner devices are more susceptible to temperature fluctuations and as such, a more thermally stable graphene layer structure is particularly advantageous to improve device lifetime.

The graphene containing-laminate further comprises a first metal oxide layer formed of a first metal oxide, wherein the first metal oxide is a transition metal oxide, and, on the first metal oxide layer, a second metal oxide layer formed of a second metal oxide. The second metal oxide layer is a dielectric layer which, as described herein, is preferably formed by ALD. Therefore, it will be appreciated that the second metal oxide is different to the first metal oxide and need not have a high work function and may therefore have a work function of less than 6 eV, less than 5.5 eV or even less than 5 eV. Preferably, the second metal oxide is selected from the group consisting of: Al₂O₃, ZnO, TiO₂, ZrO₂, HfO₂, MgAl₂O₄, YSZ, and mixtures thereof, preferably alumina (Al₂O₃) or hafnia (HfO₂), these materials being particularly suited for ALD.

The first metal oxide layer has a thickness of from 0.1 nm to 5 nm. The inventors have found that this thickness may be used to control the extent of doping of the graphene layer structure to arrive the desired charge carrier concentration whereby a greater thickness leads to more p-doping. The desired nominal thickness can be achieved through use of a Quartz Crystal Microbalance (QCM) during formation which provides the skilled person with an in-situ measurement of the amount of material deposited when carrying out the method. The thickness of the layer is therefore a mean average thickness of the layer. At thicknesses of 2 nm or less, the layer typically forms what may be known as “seeds” or “islands” without having formed a uniform layer. The thickness may then equally be readily determined by those skilled in the art using conventional techniques, for example, atomic force microscopy (AFM). Generally, a complete layer will form at greater thicknesses (e.g. more than 2 nm) such that it is preferred that the maximum thickness of any portion of the first metal oxide layer is therefore no more than 5 nm, or no more than 3 nm.

A thickness of at least 0.5 nm, for example from 0.5 to 3 nm, or from 0.5 to 2 nm has been found to be particularly suitable for providing a desirable level of doping and temperature stability. Preferably, the first metal oxide layer covers 50% or more and/or 90% or less of the area of the graphene layer structure thereby leaving the remaining 50% or less and/or 10% or more of the area of the graphene layer structure exposed during formation of the second metal oxide layer. Preferably, the second metal oxide layer has a thickness of 5 nm or more and/or 250 nm or less, preferably 10 nm or more and/or 100 nm or less, and in some embodiments, less than 20 nm, or preferably from 30 nm to 80 nm. Such a thickness provides a suitably conformal layer across the graphene layer structure and first metal oxide.

The inventors have found that layers added to the surface of graphene may continue to influence its charge carrier concentration. Without wishing to be bound by theory, intrinsic and unavoidable defects and deficiencies in the layers which are formed by physical and/or chemical deposition methods result in doping of the graphene both initially and over time through continued use. This is significantly accelerated at higher temperatures. However, a suitably thin transition metal oxide layer as a seed layer, specifically one which has a sufficiently high work function, in combination with the second metal oxide layer, provides a graphene-containing laminate with a thermally stable charge carrier concentration. This result is particularly unexpected since the “second metal oxide” alone afforded minimal additional temperature stability.

The first metal oxide layer therefore has a work function of 5 eV or more. Preferably, the first metal oxide layer has a work function of 5.5 eV or more, preferably 6 eV of more, more preferably 6.5 eV or more. Work functions of known and available metal oxides are typically no greater than 8 eV, or even 7.5 eV. For example, suitable transition metal oxides may be selected from the group consisting of: molybdenum oxide (e.g. MoO₃, MoO₂), chromium oxide (e.g. CrO₃, Cr₂O₃), vanadium oxide (V₂O₅), tungsten oxide (WO₃), nickel oxide (NiO), cobalt oxide (Co₃O₄), copper oxide (CuO), silver oxide (AgO), titanium oxide (TiO₂), tantalum oxide (Ta₂O₅), and mixtures thereof; preferably molybdenum oxide (e.g. MoO₃), chromium oxide (e.g. CrO₃), vanadium oxide, tungsten oxide, nickel oxide, and mixtures thereof; preferably molybdenum oxide, chromium oxide, and mixtures thereof. The preferred metal oxides may be simply formed directly as an oxide on the graphene layer structure, such as by PVD.

Preferably, the graphene layer structure has a charge carrier concentration of less than 5×10¹² cm⁻², preferably less than 2×10¹² cm⁻², more preferably less than 10¹² cm⁻², as a result of the combination of materials and method of manufacture described herein. The charge carrier concentration is that measured at ambient conditions (e.g. 25° C.) after manufacture is complete. A device may be manufactured incorporating the graphene-containing laminate and, as such, the charge carrier concentration refers to that of the final, as-manufactured laminate or device. In some embodiments, particularly for cryogenic temperature applications as described herein, the charge carrier density is preferably greater than 1×10¹² cm⁻², or greater than 3×10¹² cm⁻², and/or less than 8×10¹² cm⁻², for example from 4×10¹² cm⁻² to 6×10¹² cm⁻².

Preferably, the graphene layer structure has a thermally stable charge carrier concentration and/or resistivity at temperatures in excess of 50° C. That is, preferably the change in charge carrier concentration and/or resistivity is less than 0.05% per day when measured at 125° C. It is also preferred that the change in charge carrier concentration and/or resistivity is less than 0.01% per day when measured at 25° C. Such measurements may take place under ambient air having about 21 vol % O₂, and/or a relative humidity of 85% or more which is typical for automotive testing standards. Measurements of change in resistivity are generally much simpler and are indicative of changes in the charge carrier concentration.

Preferably the graphene layer structure has an electron mobility of greater than 800 cm²/Vs as a result of its novel structure and method of manufacture, preferably greater than 1000 cm²/Vs, when measured using standard techniques at room temperature (e.g. 25° C.). It is desirable to have a high mobility as this improves the device performance. The presence of dopants typically supresses the electron mobility, so by avoiding the use of dopants the electron mobility can be increased. However, the inventors have found that the first metal oxide layer formed of a transition metal oxide having a work function greater than 5 eV dopes the graphene without having a negative impact on the mobility.

A further aspect of the present invention provides an electronic device, preferably a sensor, comprising the graphene-containing laminate described herein. Examples of sensors that can benefit through being formed from such graphene-containing laminate include Hall-sensors, temperature sensors, and magneto-resistance sensors (as described in GB 2602119, GB Patent Application No. 2106821.8 and GB Patent Application No. 2115100.6, respectively, the contents of which are incorporated herein by reference in their entirety) as well as current-sensors. The electronic device comprises one or more contacts in contact with the graphene layer structure. Contacts are standard components in electronic device fabrication that are well-known to those skilled in the art and may be deposited during fabrication of the graphene-containing laminate and/or after fabrication of said laminate. Contacts provide a point of connection into an electronic circuit (such as via metal wires bonded to the contacts or through soldering using “flip chip” style solder bumps). Thus an electronic device is a functioning device when installed in an electronic circuit and current is provided to the device. As will be appreciated, a large-area graphene-containing laminate (i.e. a wafer such as one having a diameter of greater than or equal to 5 cm (2 inches)) may be processed to manufacture an array of electronic devices on the common underlying substrate. This may then be diced into individual devices such that an electronic device comprises a portion of a larger graphene-containing laminate

Typically, contacts are metal contacts, such as those formed of chromium, titanium, aluminium, nickel, tungsten and/or gold. Generally, multiple contacts are provided in contact with the graphene layer structure of the graphene-containing laminate. These may have an edge and/or surface contact with the graphene layer structure. Such contacts may be deposited by PVD techniques such as e-beam evaporation.

The architecture provided by the laminated structure of graphene, dielectric metal oxide and substrate is particularly suitable for incorporation into sensors, and most preferably Hall-sensors, though through appropriate further processing may also be used in other devices such as transistors, capacitors, diodes (including LEDs and solar cells as well as resonant tunnelling diodes) and photonic devices such as electro-optic modulators. As a result, the device is suitable for use at temperatures in excess of 50° C., preferably in excess of 100° C. whereby the graphene has a thermally stable charge carrier concentration as described herein.

In accordance with a further aspect, there is provided a use of the electronic device described herein at a temperature in excess of 50° C., preferably in excess of 100° C. and may be used at temperatures up to about 200° C. Such devices can therefore be used in high temperature applications such as the automotive industry whereby temperature stability at a temperature of about 125° C. is necessary as well as the aerospace industry whereby temperature stability at a temperature of about 180° C. is necessary.

Moreover, the inventors have found that the final device may be used at cryogenic temperatures, for example, less than 120 K. In particular, the present disclosure is concerned with the operation of devices at cryogenic temperatures no greater than: 20 K, 10 K, 5 K, 4 K, 3 K, 2 K, 1.5 K, or 1 K. The device may also be suitable for use at millikelvin temperatures (i.e. less than 1 K). In some embodiments, for example for a Hall-sensor, the device may exhibit a substantially linear temperature dependence across a wide magnetic field range, such as from −1 to +1 T, from −7 to +7 T, preferably from −14 to +14 T. In some embodiments, the Hall-sensor may exhibit a non-linearity error from a linear fit of 1% or less, preferably 0.1% or less, as measured between −1 and +1 T. In some embodiments, the device is capable of operating at temperatures of at least 1000° C., such as about 1350° C. A particularly preferred device for use at such extreme temperatures is a temperature sensor whereby the resistance of the graphene layer structure is used to determine the temperature.

The inventors have found that tungsten is a suitable metal contact for use in such a device, for example as source and drain contacts. Typically, much higher temperatures are required during tungsten deposition (for example due to its very high melting point) so as to provide an effective electrical contact between the metal and graphene. As a result, it is preferred that the tungsten metal contacts are deposited in an air and moisture atmosphere, e.g. under vacuum or an inert atmosphere.

Such a device includes a capping layer as described herein so as to fully encapsulate the graphene layer structure. For such a device to withstand such high temperatures, it is believed to be essential to fully encapsulate the graphene layer structure with an air and moisture barrier otherwise the graphene can oxidise and decompose to liberate carbon monoxide, which may even occur under nominal vacuum or inert atmosphere due to unavoidable traces of oxygen and/or moisture.

The inventors have also found that the electronic device formed from and comprising the graphene-containing laminate of the present invention is particularly stable under application of stress and/or strain forces. In particular, the inventors have found that devices such as Hall-sensors comprising such a graphene-containing laminate exhibits substantially no deviation in the baseline measurement (within the background noise which could be observed), even under application of a force sufficient to break the underlying substrate/wafer.

The stresses and strains that may be experienced by the device at die level can cause a shift in the device performance and its characteristics during the integration and packaging steps. Such packaging steps are conventional and well-known and include steps such as wafer dicing, die attachment, wire-bonding (for example with ultrasonic power) and soldering (providing heat stress). Such as shift can invalidate measurements which are taken at wafer level (or earlier in the manufacture) which may be used to filter working devices for electronic device production and which provide data for final data sheets. This can mean that measurements must be repeated thereby increasing complexity and cost. Permanent strain induced by thermal cycling in operation, from within the device or a printed circuit board assembly, will also affect the strain seen at die level. Accordingly, by reducing the impact of strain on device performance, this can aid accuracy and/or reduce complexity of any recalibration and/or supporting electronics required for compensation, and can remove the need entirely.

As such, the graphene-containing laminate and resulting device is particularly suitable for packaging which is key for commercial electronic devices. The improved stability under stress and strain is also believed to be beneficial for a packaged electronic device, such as a packaged Hall-sensor, in that the device is particularly suitable for use in automotive applications and/or at the high temperatures as described herein since the device is more robust and resilient to forces which it may experience when in use and across its lifetime.

The first metal oxide layer may be deposited using conventional means in the art, for example PVD techniques such as sputtering or evaporation (e.g. thermal evaporation). The first metal oxide layer is generally not formed by deposition of a metal and oxidation since complete oxidation of the metal to provide the metal oxide with a sufficiently high work function of 5 eV or more is unreliable without resulting in undesirable oxidation and therefore damage to the underlying graphene layer structure. Furthermore, such a method may introduce impurities which may otherwise acts as dopants which ultimately affect stability at elevated temperatures. Equally, the first metal oxide layer is generally not formed by a method which utilises a metal oxide precursor (such as a metal organic compound in particular). That is, through techniques such as PVD or the like, the first metal oxide layer may be directly formed as a metal oxide on the surface of the graphene layer structure.

The second metal oxide layer may be formed by sputtering, thermal evaporation, e-beam evaporation or ALD. Preferably, the second metal oxide layer is formed by atomic layer deposition (ALD). ALD is especially preferred since the inventors were surprised to find that this further improves temperature stability. ALD is technique known in the art. It comprises the reaction of at least two precursors in a sequential, self-limiting manner. Repeated cycles to the separate precursors allow the growth of a layer in a conformal manner (i.e. uniform thickness across the entire surface) due to the layer-by-layer growth mechanism. Alumina is a particularly preferred coating material and can be formed by sequential exposure to trimethylaluminium (TMA) and an oxygen source, preferably one or more of water (H₂O), O₂, and ozone (O₃).

Suitable precursors which provide the required inorganic element, for example aluminium or hafnium atoms for alumina and hafnia, are well-known, commercially available and not particularly limited.

Preferably, the second metal oxide layer is formed by ALD using a metal alkyl, metal alkoxide or metal halide as a metal precursor (i.e. metal alkyl is (R)ₙM, metal alkoxide is (RO)ₙM and metal halide is (X)ₙM). Metal halides such as metal chlorides (e.g. AlCl₃ and HfCl₄) may be used. Alternatively, metal amides, metal alkoxides or organometallic precursors may be used. Hafnium precursors include, for example, tetrakis(dimethylamido)hafnium(IV), tetrakis(diethylamido)hafnium(IV), hafnium(IV) tert-butoxide and dimethylbis(cyclopentadienyl)hafnium(IV). Preferably, the barrier layer is alumina and preferably the aluminium precursor for the ALD is a trialkyl aluminium or trialkoxide aluminium, such as trimethylaluminium, tris(dimethylamido) aluminium, aluminium tris(2,2,6,6-tetramethyl-3,5-heptanedionate) or aluminium tris(acetylacetonate).

In some embodiments the ALD is conducted at a relatively low deposition temperature of 80° C. or less, whereas it is very typical in the art for ALD of metal oxides to be carried out at temperatures of 150° C. or more. For example, ALD may be conducted at a temperature of 60° C. or less. In some preferred embodiments, ALD is conducted at a higher temperatures, for example up to 400° C., such as up to 300° C., for example from 100° C. to 200° C. Such temperatures may be preferable when using H₂O as a precursor to form the second metal oxide layer.

Preferably, the second metal oxide layer is formed by ALD using ozone as an oxygen precursor. Ozone is a particularly suitable oxygen precursor for the low temperature ALD. Preferably, the ozone is provided as a mixture with oxygen, preferably in a concentration of 5 to 30 wt. % (i.e. of the oxygen precursor), more preferably 10 to 20 wt. %.

ALD, particularly when using ozone, can serve to functionalise any exposed portions of the graphene layer structure having the seed layer thereon (which typically arises where the thickness is 2 nm or less). Ozone also serves to p-dope the graphene layer structure, though the inventors have found that in the absence of the transition metal oxide, the ozone p-doping is not stable on heating. For example, an alumina layer deposited by ALD onto bare graphene using ozone as a precursor does not provide a thermally stable graphene-containing laminate.

As will be appreciated, the second metal oxide layer may be formed of two or more sub-layers of metal oxide. For example, in some particularly preferred embodiments, the layer is formed of two sub-layers of metal oxide, each formed by ALD. In some preferred embodiments, the second metal oxide layer comprises two sub-layers of metal oxide, each formed of the same material such as alumina. Each sub-layer may be formed under different deposition conditions. Preferably, the lower sub-layer, which is deposited before the upper sub-layer and directly on the first metal oxide layer, is formed by ALD at a lower temperature than the upper sub-layer. Preferably, the lower sub-layer is deposited at temperatures as described hereinabove for the second metal oxide layer and/or is deposited using ozone. The lower sub-layer preferably has a thickness of 30 nm or less, preferably 20 nm or less.

The upper sub-layer(s) may be deposited at a temperature of 100° C. or more, preferably 120° C. or more. The upper sub-layer may be formed using the equivalent deposition conditions as those for the ALD of the capping layer. Preferably, the upper sub-layer is formed using H₂O as an oxygen precursor. Deposition by ALD at higher temperatures and/or using water as a precursor typically results in a dielectric layer having higher density, which, without wishing to be bound by theory, is believed to provide sufficient density to block moisture ingress through the first sub-layer. Accordingly, even where the same material is used, sub-layers may be readily detected in resulting products using conventional techniques in the art such as cross-section scanning tunnelling microscopy. The use of such sub-layers in the second metal oxide layer is particularly preferred for forming a graphene-containing laminate for use in forming a hall-sensor therefrom due to the combined benefits of suitable doping from the ozone deposited lower sub-layer to provide enhanced sensitivity whilst the upper sub-layer provides an enhanced barrier so as to afford a device which is highly sensitive (for sensing applications) and temperature stable under oxygen and moisture containing atmosphere.

Without wishing to be bound by theory, is it believed that the use of at least two-sub layers for the first layer of dielectric material can provide a more robust device. In particular, the inventors have found that blisters may form which can damage the “one-dimensional” connection between the graphene and the ohmic contact(s). These blisters are believed to result from trapped gases which remain from the deposition processes. This is a particular problem for devices for use at non-ambient temperatures whereby temperature cycling may induce liberation of the trapped gasses. In particular, the use of ozone during ALD has been observed to give rise to such a problem (whilst this may be a preferred embodiment so as to influence the charge carrier density and the problem may be addressed with the use of the further layers described herein). The method of producing the precursor may then preferably comprise a degassing step to remove such gases during production. This may result simply from the deposition of a further layer (e.g. the upper layer) which critically occurs before the photolithography steps and the deposition of ohmic contacts (and the second layer of dielectric material).

Preferably, the method further comprises forming a capping layer on the second metal oxide layer, wherein the capping layer is formed of a third metal oxide and/or metal nitride. The capping layer generally encapsulates the other layers and serves to protect the graphene layer structure from air and/or moisture contamination from the atmosphere, especially when the laminate is comprised in an electronic device. As a result, a portion of the capping layer may also be provided on the surrounding portion of the substrate directly adjacent the edges of graphene layer structure. The third metal oxide is preferably selected from the group described for the second metal oxide, i.e. the group consisting of: Al₂O₃, ZnO, TiO₂, ZrO₂, HfO₂, MgAl₂O₄, YSZ, and mixtures thereof. Preferred metal nitrides that may be used for a capping layer include silicon nitride and aluminium nitride. As for the second metal oxide layer, the capping layer is preferably formed by ALD. More preferably, the ALD is performed using H₂O as an oxygen precursor for the capping layer and/or at a temperature of 100° C. or more, e.g. about 150° C. The low temperature and/or ozone based ALD growth of the second metal oxide layer is particularly suitable for growth and doping but the inventors have found may be less dense than a layer grown at higher temperature and/or with H₂O. Accordingly, the capping layer can have a higher density than the second metal oxide layer and provides protection from contamination of the graphene layer structure in the final device from ambient air and moisture. As a result, a capping layer is particularly preferred though it will be appreciated that the benefit of thermal stability afforded by the first and second metal oxide layers can be utilised, for example, when the product is packaged or otherwise maintained in a substantially air and/or moisture free environment (e.g. under vacuum or inert atmosphere).

While the second metal oxide layer and the capping layer may be formed from the same metal oxide, and/or formed under the same conditions, in some embodiments the second metal oxide layer and the capping layer are formed from different materials and/or are deposited under different conditions, such that the formed layers are discernibly distinct.

Preferably, the capping layer is formed at a temperature of 100° C. or more. The inventors have found that during manufacture, there is an initial change in charge carrier concentration during the various processing steps, particularly when conducted at such elevated temperatures. Accordingly, the method may include an anneal step of heating to 100° C. or more, typically carried out under an inert atmosphere such a nitrogen.

A capping layer may simply be understood as a third metal oxide layer, through a capping layer will serve to encapsulate the other layers of the laminate/device and therefore encapsulate the graphene layer structure and first and second metal oxide layers. In particular, a method of manufacturing an electronic device comprising the laminate may comprise a further step of depositing contacts in contact with the graphene layer structure. Edges of the graphene layer structure may be exposed through photolithography steps, or any other suitable etching steps, to etch the graphene/first metal oxide/second metal oxide stack. Generally, such steps are used to shape the stack and therefore the graphene layer structure as desired. Preferably, the capping layer has a thickness of 50 nm or more. There is no particular upper limit, though generally the capping layer is not thicker than 500 nm, preferably less than 250 nm.

Preferably, the graphene layer structure is formed by CVD directly on the substrate. Forming may be considered synonymous with synthesising, depositing, producing and growing. CVD refers generally to a range of chemical vapour deposition techniques, each of which involve vacuum deposition to produce thin film materials such as two-dimensional crystalline materials like graphene. Volatile precursors, those in the gas phase or suspended in a gas, are decomposed to liberate the necessary species to form the desired material, carbon in the case of graphene. CVD as described herein is intended to refer to thermal CVD such that the formation of graphene from the decomposition of a carbon-containing precursor is the result of the thermal decomposition of said carbon-containing precursor.

The graphene being grown by CVD directly on the substrate therefore avoids physical transfer processing. The physical transfer of graphene, usually from copper substrates, introduces numerous defects which negatively impacts the physical and electronic properties of graphene. As such, a person skilled in the art can readily ascertain whether a graphene layer structure, and by extension a graphene-containing laminate is one comprising a CVD-grown graphene layer structure that has been grown directly on the specific materials using conventional techniques in the art such as atomic force microscopy (AFM) and energy dispersive X-ray (EDX) spectroscopy. The graphene layer structure is devoid of copper contamination and devoid of transfer polymer residues by virtue of the complete absence of these materials in the process of obtaining the graphene substrate. Furthermore, such processing is generally not suitable for large scale manufacture (such as on CMOS substrates in fabrication plants). Unintentional doping, particularly from the catalytic metal substrates together with the etching solutions, also results in the production of graphene which is not sufficiently consistent from sample to sample as is required for commercial production. Nevertheless, the advantages of thermal stability of a relatively low charge carrier concentration can still be achieved for graphene provided by other means through routine optimisation on the part of a skilled person, though the process is more laborious and therefore not amenable for mass manufacture. In other methods, graphene is grown from decomposition of the surface of a silicon carbide substrate. Whilst such a method avoids transfer, the substrate is typically more expensive than other substrates and the resulting graphene may retain some degree of covalent bonding to the substrate which is undesirable.

As will be appreciated, the CVD grown graphene is formed on a surface of a substrate which may be referred to as a growth surface of a growth substrate. Preferably, the method involves forming graphene by thermal CVD such that decomposition is a result of heating the carbon-containing precursor. Preferably, the temperature of the growth surface during CVD is from 700° C. to 1350° C., preferably from 800° C. to 1250° C., more preferably from 1000° C. to 1250° C. The inventors have found that such temperatures are effective for providing graphene growth directly on the materials described herein by CVD.

Preferably, the CVD reaction chamber used in the method disclosed herein is a cold-walled reaction chamber wherein a heater coupled to the substrate is the only source of heat to the chamber. In a particularly preferred embodiment, the CVD reaction chamber comprises a close-coupled showerhead having a plurality, or an array, of precursor entry points. Such CVD apparatus comprising a close-coupled showerhead may be known for use in MOCVD processes. Accordingly, the method may alternatively be said to be performed using an MOCVD reactor comprising a close-coupled showerhead. In either case, the showerhead is preferably configured to provide a minimum separation of less than 100 mm, more preferably less than 25 mm, even more preferably less than 10 mm, between the surface of the substrate and the plurality of precursor entry points. As will be appreciated, by a constant separation it is meant that the minimum separation between the surface of the substrate and each precursor entry point is substantially the same. The minimum separation refers to the smallest separation between a precursor entry point and the substrate surface (i.e. the surface of the metal oxide layer). Accordingly, such an embodiment involves a “vertical” arrangement whereby the plane containing the precursor entry points is substantially parallel to the plane of the substrate surface (i.e. the growth surface).

The precursor entry points into the reaction chamber are preferably cooled. The inlets, or when used, the showerhead, are preferably actively cooled by an external coolant, for example water, so as to maintain a relatively cool temperature of the precursor entry points such that the temperature of the precursor as it passes through the plurality of precursor entry points and into the reaction chamber is less than 100° C., preferably less than 50° C. For the avoidance of doubt, the addition of precursor at a temperature above ambient does not constitute heating the chamber, since it would be a drain on the temperature in the chamber and is responsible in part for establishing a temperature gradient in the chamber.

Preferably, a combination of a sufficiently small separation between the substrate surface and the plurality of precursor entry points and the cooling of the precursor entry points, coupled with the heating of the substrate to with a decomposition range of the precursor, generates a sufficiently steep thermal gradient extending from the substrate surface to the precursor entry points to allow graphene formation on the substrate surface. As disclosed in WO 2017/029470, very steep thermal gradients may be used to facilitate the formation of high-quality and uniform graphene directly on non-metallic substrates, preferably across the entire surface of the substrate. The substrate may have a diameter of at least 5 cm (2 inches), at least 15 cm (6 inches) or at least 30 cm (12 inches). Particularly suitable apparatus for the method described herein include an Aixtron® Close-Coupled Showerhead® reactor and a Veeco@ TurboDisk reactor.

Consequently, in a particularly preferred embodiment wherein the method of the present invention involves using a method as disclosed in WO 2017/029470, forming the graphene layer structure on the growth surface by CVD comprises:
providing the growth substrate on a heated susceptor in a close-coupled reaction chamber, the close-coupled reaction chamber having a plurality of cooled inlets arranged so that, in use, the inlets are distributed across the growth surface and have constant separation from the substrate;
cooling the inlets to less than 100° C. (i.e. so as to ensure that the precursor is cool as it enters the reaction chamber);
introducing a carbon-containing precursor in a gas phase and/or suspended in a gas through the inlets and into the close-coupled reaction chamber; and
heating the susceptor to achieve a growth surface temperature of at least 50° C. in excess of a decomposition temperature of the precursor, to provide a thermal gradient between the substrate surface and inlets that is sufficiently steep to allow the formation of graphene from carbon released from the decomposed precursor;
wherein the constant separation is less than 100 mm, preferably less than 25 mm, even more preferably less than 10 mm.

The most common carbon-containing precursor in the art for graphene growth is methane (CH₄). Particularly preferred organic compounds for use as carbon-containing precursors are hydrocarbons, and methods of forming graphene therefrom by CVD, are described in UK Patent Application No. 2103041.6, the contents of which is incorporated herein in its entirety.

Graphene formed directly on the substrate by such a method generally has a desirable level of intrinsic n-doping which is very suitably counteracted by the doping from the transition metal oxide layer having a high work function, the doping of which is correlated with the thickness of the layer. The “as-grown” doping level of the graphene can be fine-tuned through routine modifications of the growth process, such as through the choice of substrate, choice of precursor and growth/decomposition temperature. However, the graphene layer structure may be provided on a non-metallic surface of a substrate by known transfer techniques from, for example, copper foil, though this is less suitable for mass manufacture due to the possible variability in the electronic properties of the graphene layer structure as provided on the substrate.

In view of the foregoing description, one preferred embodiment is an electronic device, in particular a sensor (e.g. a Hall-sensor), comprising a graphene-containing laminate, and one or more contacts in contact with the graphene layer structure of the graphene-containing laminate (typically four or more for a Hall-sensor), the graphene-containing laminate comprising, in order:
a substrate (preferably sapphire though in accordance with other embodiments described herein may instead be a substrate formed of a silicon support having a non-metallic growth surface as described herein);
a graphene layer structure (preferably a graphene monolayer);
a first metal oxide layer formed of molybdenum oxide (i.e. a first metal oxide) having a thickness of from 0.5 nm to 3 nm (preferably 2 nm to 3 nm);
a second metal oxide layer formed of a second metal oxide (preferably having a thickness of from 30 nm to 80 nm);
a capping layer on the second metal oxide layer and on the surrounding portion of the substrate directly adjacent the edges of graphene layer structure and encapsulating all of the one or more contacts (though this may be etched to expose a portion of the contacts to allow for electrical connection such as through wire bonding), the capping layer formed of a third metal oxide (preferably having a thickness of 50 nm or more).

Both the second and third metal oxide layer may be formed of the same of different metal oxides (for example they may both be formed of aluminium oxide or hafnium oxide). In some embodiments, the second metal oxide layer may be formed of two or more sub-layers of metal oxide, or may be formed of a single layer.

As such, a preferred method of forming a sensor (in particular the sensor described above) is a method comprising:
providing a graphene layer structure on a substrate by CVD growth directly on the substrate;
forming a molybdenum oxide layer having a thickness of from 0.5 nm to 3 nm on the graphene layer structure by PVD; and
forming a second metal oxide layer on the molybdenum oxide layer, wherein the second metal oxide layer is formed of a second metal oxide by ALD at a temperature of 100° C. or more using H₂O as an oxygen precursor;
patterning the stack formed of the graphene layer structure, molybdenum oxide and second metal oxide (for example into a cross-shape suitable for a Hall-sensor);
forming one or more contacts each in direct contact with an edge of the graphene layer structure (and on the adjacent portion of the substrate surface exposed by the patterning);
forming a capping layer on the second metal oxide layer, all of the one or more contacts and the surrounding exposed portion of the substrate directly adjacent the remaining exposed edges of graphene layer structure, by ALD at a temperature of 100° C. or more using H₂O as an oxygen precursor, wherein the capping layer is formed of a third metal oxide and/or metal nitride. Preferably, the method further comprises etching the capping layer to expose a portion of each of the one or more contacts.

The sensor may preferably be formed as part of an array of sensors on a common substrate. The method preferably further comprises packaging the electronic device through steps such as wafer dicing, die attachment, wire-bonding and molding to form a packaged sensor.

Figures

The present invention will now be described further with reference to the following non-limiting Figures, in which:

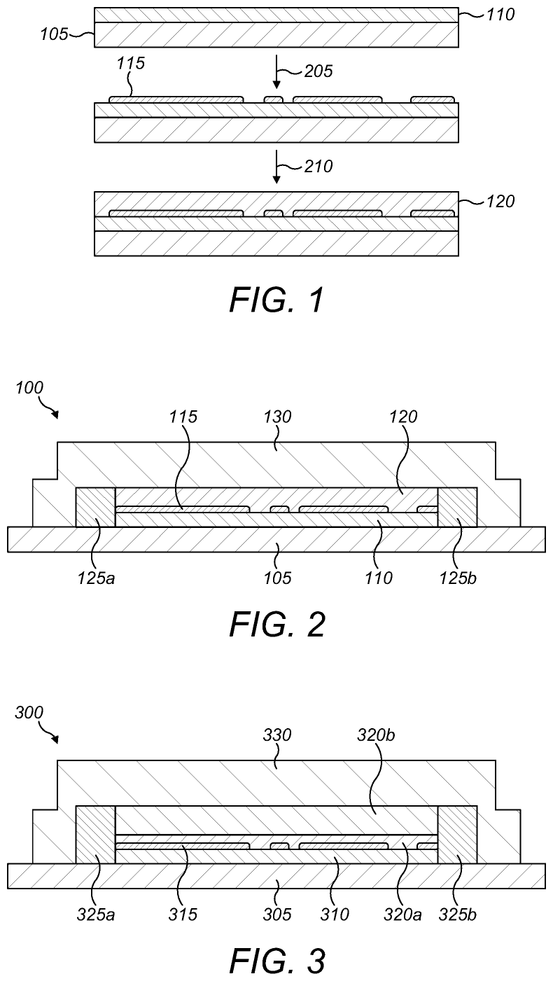

FIG. 1 illustrates a method of forming a graphene-containing laminate according to the present invention.

FIG. 2 illustrates a cross section of an electronic device comprising a graphene-containing laminate.

FIG. 3 illustrates a cross section of another electronic device comprising a graphene-containing laminate.

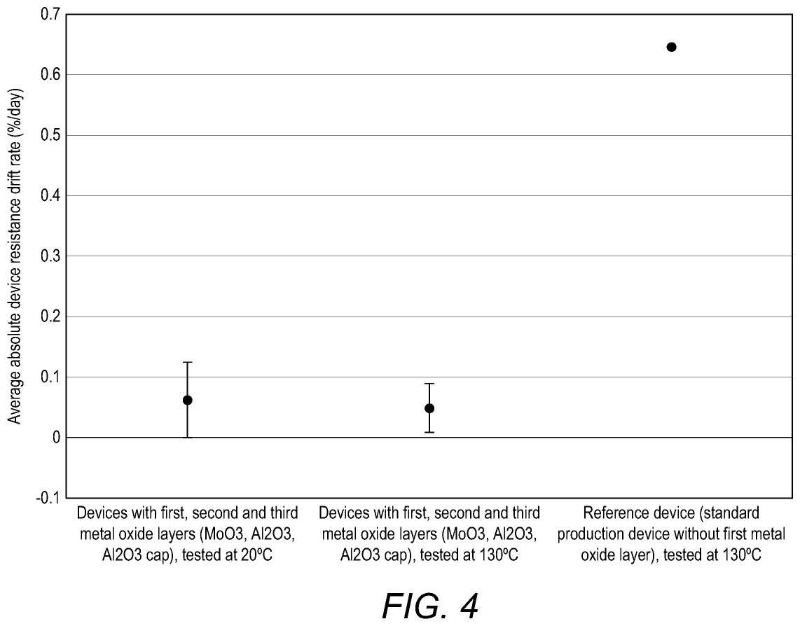

FIG. 4 is a plot of average drift rate of electronic devices according to the invention at 20° C. and 130° C., together with a comparative device at 130° C.

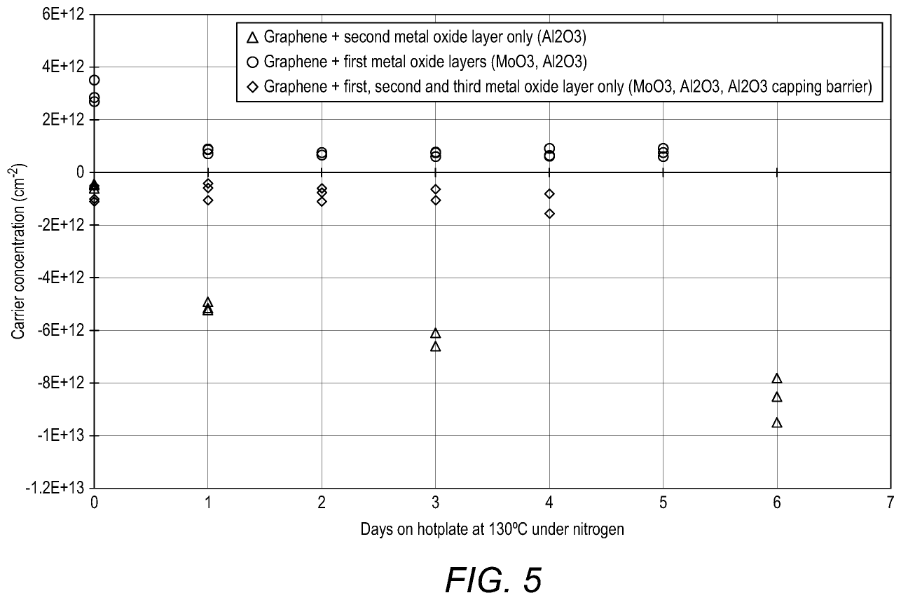

FIG. 5 is a plot which illustrates the thermal stability of various graphene-containing laminates after a number of days at 130° C.

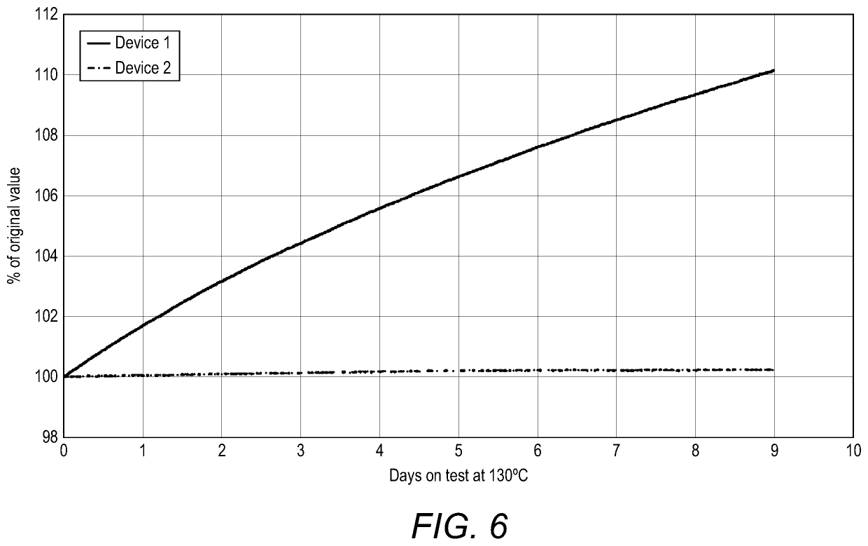

FIG. 6 is a plot of change in device resistance of the graphene against time for two Hall-sensor devices according to the present invention.

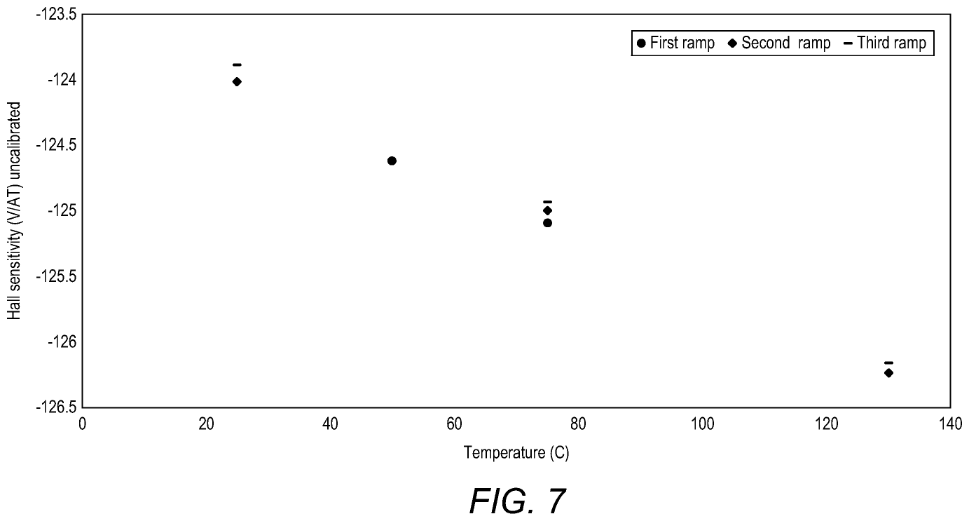

FIG. 7 is a plot of Hall sensitivity against temperature for a Hall-sensor device according to the invention across three temperature ramps.

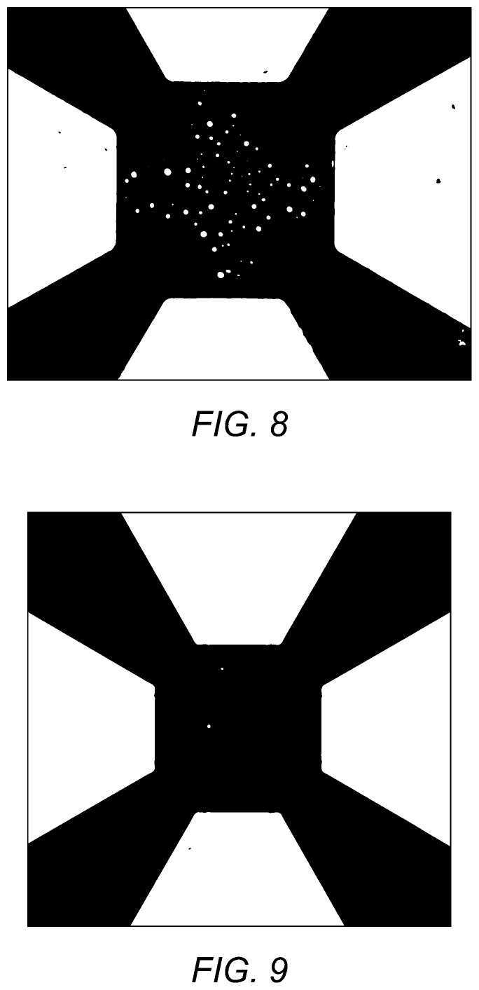

FIG. 8 is an SEM image of a Hall-sensor according to an embodiment of the present invention.

FIG. 9 is an SEM image of a Hall-sensor according to a further embodiment of the present invention.

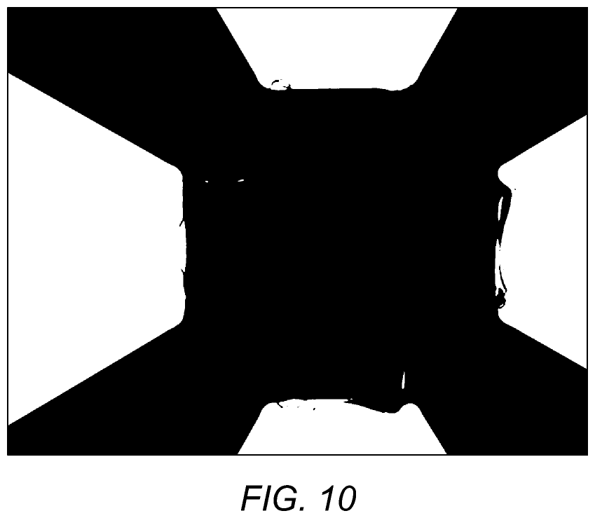

FIG. 10 is an SEM image of a Hall-sensor according to a further embodiment of the present invention.

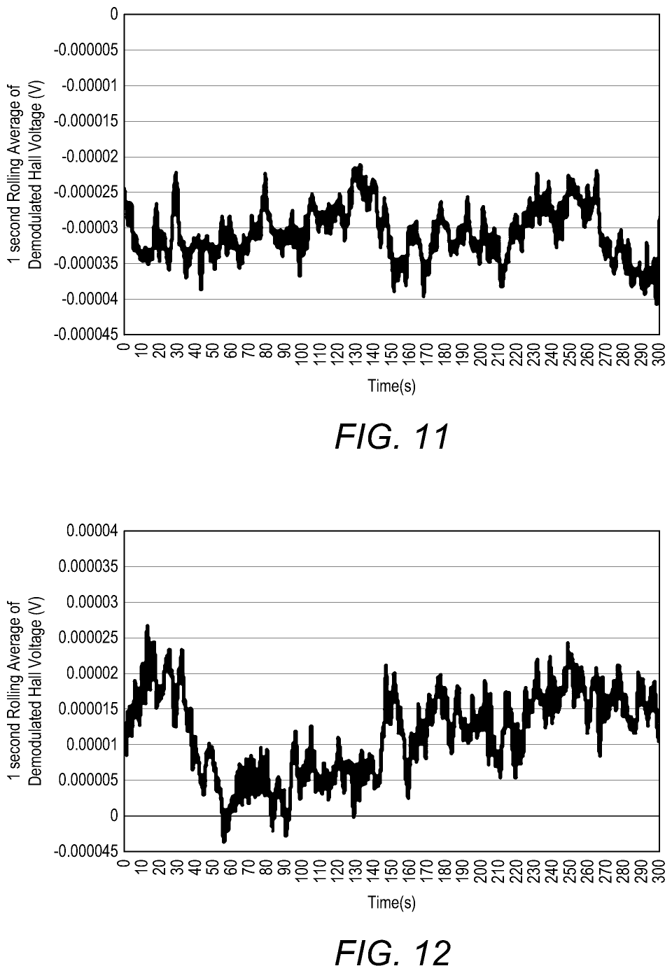

FIG. 11 is a plot of the Hall voltage (V) measured for a Hall-sensor over time(s) whilst a force of 600 gf was applied intermittently.

FIG. 12 is a control plot of the background Hall voltage (V) measured for the Hall-sensor over time(s) in the absence of a force being applied.

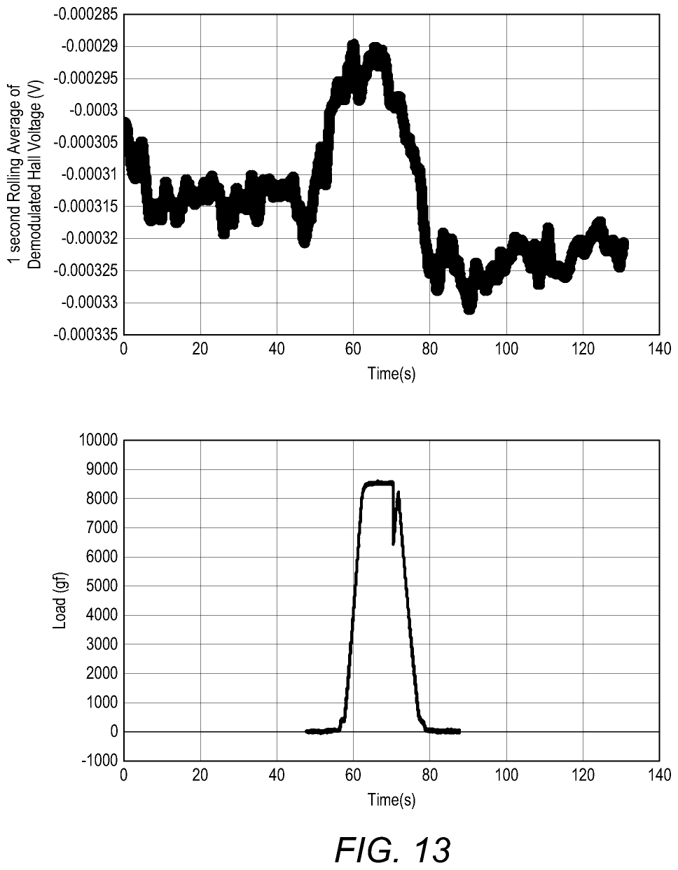

FIG. 13 is a plot of the Hall voltage (V) measured for the Hall-sensor over time(s) whilst a force of 8,500 gf was applied (top) together with the associated plot (bottom) of the force (gf) applied at the same time.

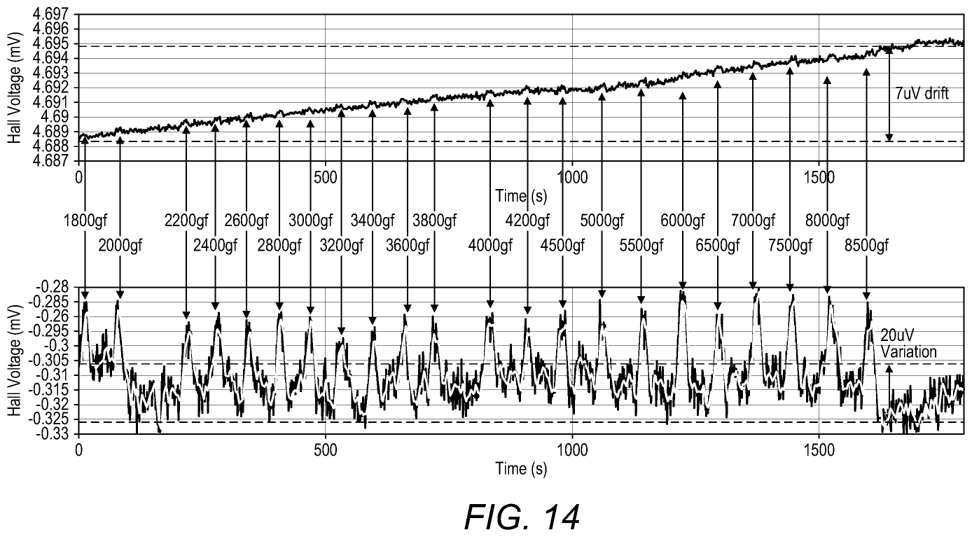

FIG. 14 provides two plots for the simultaneous measurement of the Hall voltage in which the bottom plot is a plot of the Hall voltage (mV) measured for a Hall-sensor over time(s) whilst intermittently applying an increasing force (gf) and the top plot is a control plot of the background Hall voltage (μV) measured for an adjacent Hall-sensor without applying a force.

FIG. 1 demonstrates an exemplary method in accordance with the present invention in cross-section. There is first provided a sapphire substrate 105 having a graphene monolayer 110 thereon. The graphene monolayer is preferably formed directly on the surface of the surface of the sapphire substrate 105 in a preceding step by thermal CVD.

The method then involves depositing 205 a first metal oxide layer 115 that is formed of molybdenum oxide (specifically MoO₃). The first metal oxide layer 115 has an average mean thickness of 0.1 to 5 nm (for example about 1 nm or about 2 nm) and the layer covers more than 50% of the surface area of the graphene monolayer 110. Some of the graphene monolayer remains exposed to which a second metal oxide 120 layer is deposited 210 thereon, as well as on the first metal oxide layer 115 itself. The second metal oxide layer 120 is a layer of aluminium oxide formed by ALD 210 using trimethylaluminium and ozone as precursors at a temperature of less than 60° C., preferably about 40° C. The cycles of trimethylaluminium and ozone are repeated until a thickness of about 15 nm in achieved thereby forming a graphene-containing laminate that has a thermally stable charge carrier concentration.

In another preferred embodiment, the second metal oxide layer 120 is a layer of aluminium oxide formed by ALD 210 using trimethylaluminium and H2O as precursors at a temperature of more than 100° C., such as about 150° C. Using this method, a thicker ALD layer is preferred and the second metal oxide layer 120 may have a thickness of more than 50 nm, such as about 65 nm.

FIG. 2 is a cross-section of an exemplary Hall-sensor 100 comprising a graphene-containing laminate. The graphene-containing laminate is formed of the substrate 105, graphene monolayer 110, first metal oxide layer 115 and second metal oxide layer 120 as shown in FIG. 1. For Hall-sensor 100, the substrate 105 may preferably be r-plane sapphire whereby the graphene monolayer 110 is formed on the r-plane growth surface of the substrate 105. The average mean thickness of the first metal oxide 115 in such an embodiment may be about 1 nm. In another preferred embodiment, the substrate 105 is c-plane sapphire (and the first metal oxide 115 may instead be thicker, for example from 1 to 5 nm, such as from 2 to 3 nm). The graphene monolayer 110 and first and second metal oxide layers 115, 120 have been etched and shaped into a cross-shape suitable for a Hall-sensor. Such shapes are well-known to those skilled in the art and are not particularly limited. At distal ends of the graphene monolayer 110 where the graphene-containing laminate has been etched, there are provided metal contacts 125a and 125b, each in contact with an edge of the graphene monolayer 110. The Hall-sensor 100 further comprises a capping layer 130 formed of, for example, aluminium oxide, which may also have been formed by ALD, using H₂O as the oxygen precursor at a temperature of about 150° C. until a thickness of more than 50 nm is achieved. The capping layer 130 fully encapsulates the stack of the graphene monolayer 110, first metal oxide layer 115 and second metal oxide layer 120, including any edges of the graphene monolayer 110 which have remained exposed due to etching (not visible in the cross-section of FIG. 2). The capping layer 130 may also encapsulate the metal contacts when the capping layer 130 is formed by ALD. Metal wires can be connected to the contacts straight through the capping layer 130 for connection into an electronic circuit, or preferably the capping layer 130 is etched to expose the contacts 125a and 125b. Alternatively, a patterned capping layer 130 can be deposited by a PVD technique leaving a portion of the metal contacts 125a and 125b exposed for connection of the Hall-sensor 100 into an electronic circuit. The charge carrier concentration of the final device 100 may be about 5×10¹¹ to about 10¹² cm⁻².

FIG. 3 is a cross-section of an exemplary preferred Hall-sensor 300 that is substantially equivalent to Hall-sensor 100 as shown in FIG. 2. Hall-sensor 300 comprises a graphene-containing laminate formed of the substrate 305, graphene monolayer 310, first metal oxide layer 315 (MoO₃) and second metal oxide layer. The difference is that the second metal oxide layer of Hall-sensor 300 is formed of two sub-layers 320a, 320b, each formed of aluminium oxide, for example by ALD. The lower sub-layer 320a is about 15 nm thick and formed by ALD using ozone at a temperature of less than 60° C. The upper sub-layer 320b is about 65 nm thick and formed by ALD, using H₂O as a precursor at a temperature of about 150° C.

As for Hall-sensor 100, the graphene monolayer 310 and first and second metal oxide layers 315, 320a, 320b have been etched and shaped into a cross-shape suitable for a Hall-sensor. At distal ends of the graphene monolayer 310 where the graphene-containing laminate has been etched, there are provided metal contacts 325a and 325b, each in contact with an edge of the graphene monolayer 310. The Hall-sensor 300 further comprises a capping layer 330 formed of, for example, aluminium oxide, which may also have been formed by ALD, but using H₂O as the oxygen precursor at a temperature of about 150° C. until a thickness of more than 50 nm is achieved.

The cross-section of the device in FIG. 3 is equally representative of other electronic devices, for example a temperature sensor. In an embodiment of such a device suitable for use at extremely high temperatures (e.g. greater than 1000° C.), the metal contacts 125a and 125b are formed of tungsten.

FIG. 4 is a plot of the average resistance drift rate in %/day of Hall-sensor devices according to the present invention which include an MoO₃ doping seed layer together with second and third metal oxide layers formed of Al₂O₃. The Example data in FIG. 4 shows that the resistance of the graphene layer structure has minimal drift at both 20° C. and 130° C. (generally below 0.1%/day where error bars show standard deviation within batches of devices). On the other hand, the reference Hall-sensor device without an MoO₃ layer shows much greater drift at 130° C. of about 0.65%/day.

FIG. 5 is a plot which illustrates the thermal stability of various graphene-containing laminates after a number of days at 130° C. under an inert nitrogen atmosphere. A comparative graphene-containing laminate comprises a substrate, graphene and a “second metal oxide layer” formed of Al₂O₃ directly thereon (i.e. without a first transition metal oxide with high work function; plotted with triangles). In the absence of such layer, the measured carrier concentration is not thermally stable and quickly increases to more than 5×10¹² cm⁻² (in absolute terms) within 1 day and continues to increase.

A first inventive graphene-containing laminate comprises a substrate, graphene, a first MoO₃ layer and a second Al₂O₃ layer (plotted with circles). A second inventive graphene-containing laminate is based on the first and further comprises a third capping Al₂O₃ layer (plotted with diamonds). The inventive graphene-containing laminates comprising an MoO₃ doping seed layer provides the graphene layer structure with improved thermal stability. After more than 4 or 5 days at 130° C., the carrier concentration remains below 2×10¹² cm⁻², and generally below 10¹² cm⁻².

The inventive example which does not include a capping layer shows an initially high carrier concentration which rapidly stabilises at 130° C. to a value below 2×10¹² cm⁻². Whilst samples may show an initial change upon heating directly after manufacture, samples stabilise to the desired values generally within 1 day, for example within about 8 hours. As regards the stability parameters discussed herein, these are measured from a starting point 12 hours after manufacture of the final electrical component (e.g. hall sensor) to ensure that this initial stabilisation has finished.

FIG. 6 is a plot of change in charge carrier concentration of the graphene against time (in days) for two Hall-sensor devices according to the present invention. Device 1 is manufactured in accordance with Method 3 and Device 2 manufactured in accordance with Method 4. For both devices, the laminate was exposed to atmosphere and chemicals before the deposition of the capping layer (i.e. after photolithography processing of the second metal oxide layer). Device 1 shows about a 10% change in device resistance after about 9 days whereas Device 2 shows negligible change after the same period of time. FIG. 6 shows that the second metal oxide layer being formed of two sub-layers improves the stability of the final device.

FIG. 7 is a plot of Hall sensitivity against temperature for a Hall-sensor device manufactured in accordance with Method 4 across three temperature ramps. The data shows a linear change in Hall sensitivity across multiple temperature ramps up to about 180° C. The device was secured on a heated plate and the hall properties of the device measured using the Van der Pauw method. The stage was heated and allowed to stabilise, then several Hall measurements were taken and averaged. This was repeated at various temperatures. Ramp1 maximum temperature was 75 C, Ramp 2 maximum temperature was 130 C and Ramp 3 maximum temperature was 180 C.

FIGS. 8-10 are SEM images of different embodiments of Hall-sensor devices in accordance with the present invention comprising a graphene-containing laminate as described herein. Each of these Hall-sensors is formed of a sapphire substrate and a monolayer of graphene shaped into a cross. Each sensor also comprises a first metal oxide layer on and across the monolayer of graphene formed of MoO₃ having a nominal thickness of about 1 nm. Each device comprises a different second metal oxide layer but have an equivalent alumina capping layer.

In the device of FIG. 8, the second metal oxide layer formed on the first metal oxide layer is formed of alumina by ALD. The device of FIG. 8 includes the same ALD alumina layer as the device of FIG. 8 (e.g. as a lower sub-layer), but the second metal oxide layer of the device of FIG. 9 is further formed of a further alumina layer by ALD under different conditions (e.g. as an upper sub-layer formed by ALD using water as a precursor). The device of FIG. 10 is equivalent to that of FIG. 9, with the exception that the lower sub-layer of alumina is formed by evaporation.

As can be seen from the SEM images, the inventors have found that, in some embodiments, blistering of the graphene can occur. The blistering is found to become more evident during use of the device at either elevated temperatures or cryogenic temperatures and the associated temperature cycling to ambient temperatures. These blisters are believed to result from trapped gases which remain from the deposition processes. Blistering is undesirable due to the increased risk of damaging the contact between the graphene and the contact. The addition of a sub-layer to the second metal oxide layer is shown by FIG. 9 to reduce the prevalence of such blisters. Additionally, the blisters were further reduced through forming the lower sub-layer of the second metal oxide by evaporation.

### Examples

### Method 1

A graphene monolayer is grown directly onto the surface of a sapphire substrate in accordance with the method of WO 2017/029470. Hall-sensor devices were then manufactured using said graphene on sapphire in accordance with the method disclosed in GB 2602119 with the exception that a layer of MoO₃ is first deposited across the graphene monolayer via thermal evaporation at ambient temperature until a nominal thickness of 1 nm is achieved, as measured by QCM.

The second metal oxide layer formed of Al₂O₃ is formed on the MoO₃ layer as a Hall-cross shape through a shadow mask via e-beam evaporation. Oxygen plasma etching removes graphene not protected by the cross. Metal contacts are deposited via evaporation through a shadow mask (10 nm Ti via e-beam and 200 nm Au via thermal). An Al₂O₃ capping layer is deposited by ALD at 150° C. until a thickness of about 65 nm is achieved. The devices are then singulated and wirebonded into LCC packages.

The packages are placed into test sockets in a controlled chamber that is heated to 130° C. under an atmosphere of ambient air with the device resistance monitored for the duration of the test period. The results are shown in FIG. 4. The reference device is that made without an MoO₃ layer, directly in accordance with GB 2602119, the resistance drift having been measured via periodic Hall-measurements at ambient temperature before and after heating.

### Method 2

A graphene monolayer is grown directly onto the surface of a sapphire substrate in accordance with the method of WO 2017/029470. A layer of MoO₃ is deposited across the graphene monolayer via thermal evaporation at ambient temperature until a nominal thickness of 1 nm is achieved, as measured by QCM.

To the MoO₃ coated graphene monolayer, a layer of Al₂O₃ is deposited by ALD at a temperature of about 40° C. using ozone as an oxygen precursor. Cycles of oxygen and aluminium precursors are repeated until a thickness of about 15 nm is achieved.

Optionally, a capping layer formed of Al₂O₃ is deposited by ALD at a temperature of 150° C. until a thickness of about 65 nm is achieved.

1 cm square samples are cleaved from the wafer (i.e. with or without the capping layer) for testing. The carrier concentration is measured initially (day 0) and the samples are then placed on a hotplate at about 130° C. under nitrogen. Periodically, the samples are removed from the hotplate and the carrier concentration measured. The results are shown in FIG. 5.

In a comparative example, a graphene monolayer is identically grown directly onto the surface of a sapphire substrate in accordance with the method of WO 2017/029470. To the graphene monolayer, a layer of Al₂O₃ is deposited by ALD at a temperature of about 40° C. using ozone as an oxygen precursor. Cycles of oxygen and aluminium precursors are again repeated until a thickness of about 15 nm is achieved. The comparative results are also shown in FIG. 5.

### Method 3

A graphene monolayer is grown directly onto the surface of a sapphire substrate in accordance with the method of WO 2017/029470. A layer of MoO₃ is deposited across the graphene monolayer via thermal evaporation at ambient temperature until a nominal thickness of 1 nm is achieved, as measured by QCM.

To the MoO₃ coated graphene monolayer, a 15 nm layer of Al₂O₃ is deposited by ALD at a temperature of about 40° C. using ozone as an oxygen precursor. The Al₂O₃ layer and underlying graphene is then patterned into a Hall-sensor cross using conventional photolithography and etching techniques. Contacts are then deposited to contact the edges of the graphene. A capping layer formed of Al₂O₃ is deposited by ALD at a temperature of 150° C. until a thickness of about 65 nm is achieved.

This device is in accordance with Device 1 in FIG. 6.

### Method 4

A graphene monolayer is grown directly onto the surface of a sapphire substrate in accordance with the method of WO 2017/029470. A layer of MoO₃ is deposited across the graphene monolayer via thermal evaporation at ambient temperature until a nominal thickness of 1 nm is achieved, as measured by QCM.

To the MoO₃ coated graphene monolayer, a 15 nm (sub) layer of Al₂O₃ is deposited by ALD at a temperature of about 40° C. using ozone as an oxygen precursor directly followed by the formation of a further 65 nm (sub) layer of Al₂O₃, but at a temperature of about 150° C. using H₂O as a precursor. The Al₂O₃ layer and underlying graphene is then patterned into a Hall-sensor cross using conventional photolithography and etching techniques. Contacts are then deposited to contact the edges of the graphene. A capping layer formed of Al₂O₃ is deposited by ALD at a temperature of 150° C. until a thickness of about 65 nm is achieved.

This device is in accordance with Device 2 in FIG. 6.

### Stress Testing

An inventive Hall-sensor manufactured in accordance with Method 3 above was used as a primary Hall-sensor for stress testing (with the exception that the Hall-sensor was formed with a 65 nm layer of Al₂O₃ onto the MoO₃ coated graphene monolayer rather than a 15 nm layer).

The tests conducted were based on a typical four-point flexural stress test. The tests were performed on an about 3×3.5 cm sapphire wafer via two anvils each with two rollers whereby the lower anvil's rollers were spaced 2 cm apart. The tests were performed in a temperature-controlled environment at a temperature of 22° C.

Hall-sensors were wire bonded to a flexible PCB which was affixed to the wafer by adhesive. Wires were then soldered to the PCB and connected to a set of screw terminals on a perforated stripboard with attached contact pins for the connection of test leads. Hook probe and crocodile clip test leads were used to connect the contact pins to a Keithley 2450 power supply and a MiST test box, respectively.

A magnetic field was applied via a strong permanent magnet directly beneath the primary Hall-sensor to be tested. A secondary non-stressed (control) Hall-sensor was positioned between the permanent magnet and the primary Hall-sensor, about 1 cm below the wafer and between the lower rollers of the anvil. The permanent magnet produced a Hall voltage of about 300 μV in the primary Hall-sensor as shown in FIG. 13 (top plot).

During the application of a force (i.e. stress/strain or a load) to the wafer, spinning current measurements were taken on the MIST and non-spin with the Keithley. The data shown in the Figures is based on the MIST data only. In all tests, the loading rate was 8,000 gf/s. For the former measurement, the spin rate was 1 kHz and 150 μs settling time, 200 μA drive current and a gain of 100. The Keithley 2450 provided a non-spinning steady drive current of 200 μA to another on-wafer sensor while also measuring the Hall voltage.

Repeated measurements were performed at a force nominally equivalent to 600 g of weight (600 gf) to apply stress to the wafer whilst measuring the Hall-voltage for both the primary and secondary sensors. The results are shown in FIGS. 11 and 12 (for the primary and secondary sensors, respectively, recorded simultaneously). Both plots of Hall-voltage over time show background noise only showing that no change in Hall-voltage could be observed due to the force and stress applied during the test.

The test was repeated and performed at a force nominally equivalent to 8.5 kg (8,500 gf). The results are shown in FIG. 13 in which a change in the measured Hall-voltage of the primary sensor of about 20 μV could be observed (top plot) under application of the force (bottom plot). The force/load profile as shown in the bottom plot clearly illustrates a discontinuity which corresponds to the point at which the wafer broke.

The test was repeated by intermittently applying an increasing force, starting at 1800 gf and increasing in increments of 200 gf up to a force of 4,200 gf, and then from 4,500 gf in increments of 500 gf up to a force of 8,500 gf. The results are shown in FIG. 14 (for both the primary and secondary sensors, recorded simultaneously). The data shows that a similar variation in the Hall-voltage of about 30 μV can be observed in the primary sensor upon each application of a force in which there is a slight increase in the variation upon increasing the force applied. There is also a noticeable change in the reference signal of the secondary sensor (top plot) indicating that the change in signal may not be attributed solely to the stress applied.

Crucially, the data shows that there is no baseline variation as a result of the stress applied and that the wafer sensing element long-term sensitivity does not appear to be affected by the test, even after wafer breakage, and the sensor returns to its ordinary operation. A variation of about 20 μV is believed to relate to the variation in angle of the sensor in relation to the applied magnetic field angle during wafer bending. Likewise, a drift of about 7 μV was observed in the reference sensor and is not observed in the primary sensor due to the greatly reduced distance between the magnet and the secondary referenced sensor.

As used herein, the singular form of “a”, “an” and “the” include plural references unless the context clearly dictates otherwise. The use of the term “comprising” is intended to be interpreted as including such features but not excluding other features and is also intended to include the option of the features necessarily being limited to those described. In other words, the term also includes the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

It will be understood that, although the terms “first”, “second”, etc. may be used herein to describe various elements, layers and/or portions, the elements, layers and/or portions should not be limited by these terms. These terms are only used to distinguish one element, layer or portion from another, or a further, element, layer or portion. It will be understood that the term “on” is intended to mean “directly on” such that there are no intervening layers between one material being said to be “on” another material. Spatially relative terms, such as “under”, “below”, “beneath”, “lower”, “over”, “above”, “upper” and the like, may be used herein for ease of description to describe one element or feature's relationship to another element(s) or feature(s). It will be understood that the spatially relative terms are intended to encompass different orientations of the device in use or operation in addition to the orientation depicted in the figures. For example, if a device as described herein is turned over, elements described as “under” or “below” other elements or features would then be oriented “over” or “above” the other elements or features. Thus, the example term “under” can encompass both an orientation of over and under. The device may be otherwise oriented and the spatially relative descriptors used herein interpreted accordingly.

The foregoing detailed description has been provided by way of explanation and illustration, and is not intended to limit the scope of the appended claims. Many variations of the presently preferred embodiments illustrated herein will be apparent to one of ordinary skill in the art, and remain within the scope of the appended claims and their equivalents.

1. A graphene-containing laminate comprising, in order:
a substrate;
a graphene layer structure;
a first metal oxide layer formed of a first metal oxide, wherein the first metal oxide is a transition metal oxide; and
a second metal oxide layer formed of a second metal oxide;
wherein the first metal oxide layer has a thickness of from 0.1 nm to 5 nm; and
wherein the first metal oxide layer has a work function of 5 eV or more.

2. The graphene-containing laminate according to claim 1, wherein the first metal oxide layer has a work function of 5.5 eV or more.

3. The graphene-containing laminate according to claim 1, wherein the transition metal oxide is selected from the group consisting of: molybdenum oxide, chromium oxide, vanadium oxide, tungsten oxide, nickel oxide, and mixtures thereof.

4. The graphene-containing laminate according to claim 1, further comprising a capping layer on the second metal oxide layer, wherein the capping layer is formed of a third metal oxide and/or metal nitride.

5. The graphene-containing laminate according to claim 1, wherein the thickness of the first metal oxide layer is 0.5 nm or more and/or 3 nm or less.

6. The graphene-containing laminate according to claim 1, wherein the first metal oxide layer covers 50% or more and/or 90% or less of the area of the graphene layer structure.

7. The graphene-containing laminate according to claim 1, wherein the second metal oxide layer has a thickness of 5 nm or more and/or 250 nm or less.

8. (canceled)

9. The graphene-containing laminate according to claim 1, wherein the substrate comprises sapphire, YSZ or CaF₂.

10. The graphene-containing laminate according to claim 1, wherein the graphene layer structure has a charge carrier concentration of less than 5×10¹² cm⁻².

11. The graphene-containing laminate according to claim 1, wherein the graphene layer structure has a thermally stable resistance at temperatures in excess of 50° C.

12. The graphene-containing laminate according to claim 11, wherein the change in resistance of the graphene layer structure is less than 0.05% per day when measured at 125° C.

13. An electronic device comprising the graphene-containing laminate according to any preceding claim, and one or more contacts in contact with the graphene layer structure.

14. The electronic device according to claim 13, wherein the device is for use at temperatures in excess of 50° C.

15. The electronic device according to claim 13, wherein the electronic device is a Hall-sensor.

16. Use of the electronic device according to claim 13 at a temperature in excess of 50° C.

17. A method of forming a graphene-containing laminate, the method comprising:
providing a graphene layer structure on a substrate;
forming a first metal oxide layer on the graphene layer structure, wherein the first metal oxide layer is formed of a transition metal oxide and has a work function of 5 eV or more; and
forming a second metal oxide layer on the first metal oxide layer, wherein the second metal oxide layer is formed of a second metal oxide;
wherein the first metal oxide layer has a thickness of from 0.1 nm to 5 nm.

18. The method according to claim 17, wherein the first metal oxide is formed by PVD.

19. The method according to claim 17, wherein the second metal oxide layer is formed by atomic layer deposition (ALD) at a temperature of 80° C. or less.

20. (canceled)

21. The method according to claim 17, further comprising forming a capping layer on the second metal oxide layer, wherein the capping layer is formed of a third metal oxide and/or metal nitride.

22. (canceled)

23. The graphene-containing laminate according to claim 9, wherein the sapphire is c-plane or r-plane sapphire.
